(19) United States
(12) Patent Application Publication
(10) Pub. No.: US 2007/0207574 A1
(43) Pub. Date: Sep. 6, 2007

(54) Double gate thin-film transistor and method for forming the same

(75) Inventors: Liang-Tang Wang, Tainan City (TW); Min-Chuang Wang, Chiayi City (TW); I-Hsuan Peng, Hsinchu County (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/520,763

(22) Filed: Sep. 14, 2006

(30) Foreign Application Priority Data
Mar. 3, 2006 (TW) 095107187

(51) Int. Cl. H01L 21/84; H01L 21/00

(52) U.S. Cl. 438/149; 257/E29.151

(57) ABSTRACT

A double-gate thin-film transistor and a method for forming the same, using low-temperature poly-silicon formed by direct deposition on a substrate so as to simplify the manufacturing process and improve the electrical characteristics. The double-gate thin-film transistor comprises: a first patterned electrode formed on a substrate; a first dielectric layer; a poly-silicon film, formed by direct deposition on the first dielectric layer so as to form between the poly-silicon film and the first dielectric layer an incubation layer comprising amorphous silicon; a pair of second patterned electrodes, formed on the poly-silicon film so as to define in the poly-silicon film and the incubation layer between the second patterned electrodes a channel region corresponding to the first patterned electrode; a second dielectric layer; and a third patterned electrode corresponding to the channel region. The method comprises steps of: providing a substrate, a first patterned electrode being formed on the substrate; forming a first dielectric layer; forming a poly-silicon film by direct deposition on the first dielectric layer so as to form between the poly-silicon film and the first dielectric layer an incubation layer comprising amorphous silicon; forming a pair of second patterned electrodes on the poly-silicon film so as to define in the poly-silicon film and the incubation layer between the second patterned electrodes a channel region corresponding to the first patterned electrode; forming a second dielectric layer; and forming a third patterned electrode corresponding to the channel region.

### BACKGROUND OF THE INVENTION

1. Field of the Invention

The present invention generally relates to a thin-film transistor and a method for forming the same and, more particularly, to a double gate thin-film transistor and a method for forming the thin-film transistor, using a poly-silicon film by direct deposition at low temperatures so as to simply the processing and improve electrical characteristics.

2. Description of the Prior Art

In semiconductor manufacturing, since the amorphous silicon film can be deposited on a glass substrate at low temperatures, thin-film transistors (TFTs) comprising amorphous silicon are widely used in the field of liquid crystal displays (LCDs).

However, the carrier mobility in an amorphous silicon film is much lower than that in a poly-silicon film, so that conventional amorphous silicon TFT-LCDs exhibit a relatively slow response time that limits their suitability for large-area LCD devices. Though there have been lots of reports on converting low-temperature grown amorphous silicon films into poly-silicon films using laser annealing, laser annealing is disadvantageous in high facility cost and considerable reliability issues due to poor resistance of the substrate to the heat.

Poly-silicon films directly grown at low temperatures are used to manufacture thin-film transistors at low cost. However, as shown in FIG. 1, when a poly-silicon film 140 is to be grown at a low temperature on a substrate 110, an incubation layer 1401 comprising amorphous silicon is usually formed due to non-periodical arrangement of silicon atoms at the early stage. For a bottom gate thin-film transistor using a low-temperature grown poly-silicon film, the ON-current is as low as 0.1 nA and the carrier mobility is as low as 2 cm²/V-s because the channel region includes an incubation layer comprising amorphous silicon. For a top gate thin-film transistor using a low-temperature grown poly-silicon film, it requires more complicated manufacturing processing.

Therefore, there exists a need in providing a double gate thin-film transistor and a method for forming the same, using a poly-silicon film by direct deposition at low temperatures so as to simply the processing and improve electrical characteristics.

### SUMMARY OF THE INVENTION

It is a primary object of the present invention to provide a double gate thin-film transistor using a poly-silicon film by direct deposition at low temperatures so as to improve electrical characteristics.

It is a secondary object of the present invention to provide a double gate thin-film transistor using a transparent conductive electrode as a top gate so as to be used in large-area and high-resolution displays.

It is another object of the present invention to provide a method for forming a double gate thin-film transistor using a poly-silicon film by direct deposition at low temperatures so as to simply the processing and reduce cost.

In order to achieve the foregoing objects, the present invention provides a double-gate thin-film transistor, comprising: a first patterned electrode formed on a substrate; a first dielectric layer, covering the first patterned electrode and the substrate; a poly-silicon film, formed by direct deposition on the first dielectric layer so as to form between the poly-silicon film and the first dielectric layer an incubation layer comprising amorphous silicon; a pair of second patterned electrodes, formed on the poly-silicon film so as to define in the poly-silicon film and the incubation layer between the second patterned electrodes a channel region corresponding to the first patterned electrode; a second dielectric layer, covering the pair of second patterned electrodes and the channel region; and a third patterned electrode corresponding to the channel region.

The present invention further provides a method for forming a double-gate thin-film transistor, comprising steps of: forming a first patterned electrode on a substrate; forming a first dielectric layer, covering the first patterned electrode and the substrate; forming a poly-silicon film by direct deposition on the first dielectric layer so as to form between the poly-silicon film and the first dielectric layer an incubation layer comprising amorphous silicon; forming a pair of second patterned electrodes on the poly-silicon film so as to define in the poly-silicon film and the incubation layer between the second patterned electrodes a channel region corresponding to the first patterned electrode; forming a second dielectric layer, covering the pair of second patterned electrodes and the channel region; and forming a third patterned electrode corresponding to the channel region.

Preferably, the substrate is selected from a group including a glass substrate, a flexible substrate and a conductive substrate having an insulating layer formed thereon.

Preferably, the first patterned electrode comprises a material selected from a group including metal, metal oxide, poly-silicon, conductive polymer and combination thereof.

Preferably, the first dielectric layer comprises a material selected from a group including oxide, nitride, insulating polymer and combination thereof.

Preferably, the pair of second patterned electrodes comprise a material selected from a group including metal, metal oxide, poly-silicon, conductive polymer and combination thereof.

Preferably, the second dielectric layer comprises a material selected from a group including oxide, nitride, insulating polymer and combination thereof.

Preferably, the third patterned electrode is at least partially overlapped with the pair of second patterned electrodes.

Preferably, the third patterned electrode is not overlapped with neither of the second patterned electrodes.

Preferably, the third patterned electrode comprises a material selected from a group including metal, metal oxide, poly-silicon, conductive polymer and combination thereof.

Preferably, the third patterned electrode is a transparent conductive electrode.

Preferably, the transparent conductive electrode comprises indium-tin oxide (ITO).

### BRIEF DESCRIPTION OF THE DRAWINGS

The objects, spirits and advantages of the preferred embodiment of the present invention will be readily understood by the accompanying drawings and detailed descriptions, wherein:

FIG. 1 is a cross-sectional view of a poly-silicon film formed on a substrate;

FIG. 2 is a cross-sectional view of a double-gate thin-film transistor according to the present invention; and

FIG. 3 is a flow chart showing a method for forming a double-gate thin-film transistor according to the present invention.

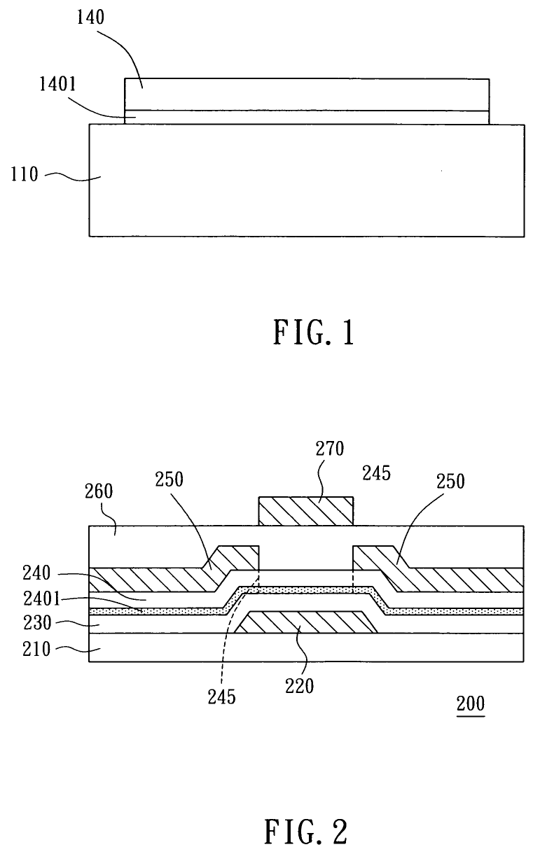

### DETAILED DESCRIPTION OF THE PREFERRED EMBODIMENT

The present invention providing a double gate thin-film transistor and a method for forming the same can be exemplified by the preferred embodiment as described hereinafter.

Please refer to FIG. 2, which is a cross-sectional view of a double-gate thin-film transistor according to the present invention. In the present invention, the double-gate thin-film transistor 200 comprises: a first patterned electrode 220 formed on a substrate 210; a first dielectric layer 230, covering the first patterned electrode 220 and the substrate 210; a poly-silicon film 240, formed by direct deposition on the first dielectric layer 230 so as to form between the poly-silicon film 240 and the first dielectric layer 230 an incubation layer 2401 comprising amorphous silicon; a pair of second patterned electrodes 250, formed on the poly-silicon film 240 so as to define in the poly-silicon film 240 and the incubation layer 2401 between the second patterned electrodes 250 a channel region 245 corresponding to the first patterned electrode 220; a second dielectric layer 260, covering the pair of second patterned electrodes 250 and the channel region 245; and a third patterned electrode 270 corresponding to the channel region 245.

In the present embodiment, the substrate 210 is a glass substrate, a flexible substrate or a conductive substrate having an insulating layer formed thereon. The first patterned electrode 220 comprises at least metal, metal oxide, poly-silicon, conductive polymer or combination thereof. In practical use, the first patterned electrode 220 functions as the bottom gate for the thin-film transistor 200.

The first dielectric layer 230 comprises at least oxide, nitride, insulating polymer or combination thereof. In practical use, the first dielectric layer 230 functions to form a bias from the bottom gate to the channel region 245 for the thin-film transistor 200 so as to control the cross-sectional area perpendicular to the current flow in the channel region 245 as well as the current.

The pair of second patterned electrodes 250 comprise at least metal, metal oxide, poly-silicon, conductive polymer or combination thereof. In practical use, the pair of second patterned electrodes 250 function as the drain and the source for the thin-film transistor 200.

The second dielectric layer 260 comprises at least oxide, nitride, insulating polymer or combination thereof. In practical use, the second dielectric layer 260 functions to form a bias from the top gate to the channel region 245 for the thin-film transistor 200 so as to control the cross-sectional area perpendicular to the current flow in the channel region 245 as well as the current.

The third patterned electrode 270 comprises at least metal, metal oxide, poly-silicon, conductive polymer or combination thereof. In practical use, the first patterned electrode 270 functions as the top gate for the thin-film transistor 200. Alternatively, when a transparent conductive material (such as indium-tin oxide, ITO) is used to form the top gate for the thin-film transistor 200, the top gate can be used as a pixel electrode for a display. Therefore, the double-gate thin-film transistor 200 of the present invention can be used in a display.

In the present embodiment, the third patterned electrode 270 is at least partially overlapped with the pair of second patterned electrodes 250. Alternatively, the third patterned electrode 270 is not overlapped with neither of the second patterned electrodes 250.

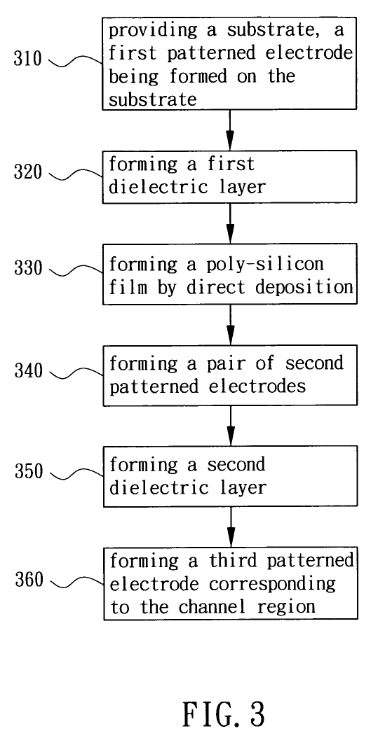

The present invention: further provides a method for forming a double-gate thin-film transistor according to the present invention, as described in the flow chart in FIG. 3. The method comprises steps as described hereinafter:

To begin with, in Step 310, a first patterned electrode is a formed on a substrate. In the present embodiment, the substrate is a glass substrate, a flexible substrate or a conductive substrate having an insulating layer formed thereon. The first patterned electrode comprises at least metal, metal oxide, poly-silicon, conductive polymer or combination thereof. In practical use, the first patterned electrode functions as the bottom gate for the thin-film transistor.

In Step 320, a first dielectric layer is formed covering the first patterned electrode and the substrate. The first dielectric layer comprises at least oxide, nitride, insulating polymer or combination thereof. In practical use, the first dielectric layer functions to form a bias from the bottom gate to the channel region for the thin-film transistor so as to control the cross-sectional area perpendicular to the current flow in the channel region as well as the current.

In Step 330, a poly-silicon film is formed by direct deposition on the first dielectric layer so as to form between the poly-silicon film and the first dielectric layer an incubation layer comprising amorphous silicon. At the early stage of forming a poly-silicon film at low temperatures, an incubation layer comprising amorphous silicon is usually formed due to non-periodical arrangement of silicon atoms.

Later, in Step 340, a pair of second patterned electrodes are formed on the poly-silicon film so as to define in the poly-silicon film and the incubation layer between the second patterned electrodes a channel region corresponding to the first patterned electrode. The pair of second patterned electrodes comprise at least metal, metal oxide, poly-silicon, conductive polymer or combination thereof. In practical use, the pair of second patterned electrodes function as the drain and the source for the thin-film transistor.

In Step 350, a second dielectric layer is formed covering the pair of second patterned electrodes and the channel region. The second dielectric layer comprises at least oxide, nitride, insulating polymer or combination thereof. In practical use, the second dielectric layer functions to form a bias from the top gate to the channel region for the thin-film transistor so as to control the cross-sectional area perpendicular to the current flow in the channel region as well as the current.

Finally, in Step 360, a third patterned electrode is formed corresponding to the channel region. The third patterned electrode comprises at least metal, metal oxide, poly-silicon, conductive polymer or combination thereof. In practical use, the first patterned electrode functions as the top gate for the thin-film transistor. Alternatively, when a transparent conductive material (such as indium-tin oxide, ITO) is used to form the top gate for the thin-film transistor, the top gate can be used as a pixel electrode for a display. Therefore, the double-gate thin-film transistor of the present invention can be used in a display.

In the present embodiment, the third patterned electrode is at least partially overlapped with the pair of second patterned electrodes. Alternatively, the third patterned electrode is not overlapped with neither of the second patterned electrodes.

For the double gate thin-film transistor of the present invention, when a positive bias voltage is applied on the top/bottom gate to the channel region, the channel region is quickly inversed such that the threshold voltage is reduced. More particularly, when the positive bias voltage is larger than the threshold voltage, the amorphous channel region is inversed due to the positive bias voltage from the bottom gate to the channel region and the poly-silicon channel region is inversed due to the positive bias voltage from the top gate to the channel region. Therefore, a carrier transportation path is formed both in the amorphous channel region and the poly-silicon channel region, such that the ON-current as well as the carrier mobility of the double gate thin-film transistor can be enhanced.

On the contrary, when a negative bias voltage is applied on the top/bottom gate to the channel region, the amorphous channel region is depleted due to the negative bias voltage from the bottom gate to the channel region, while the poly-silicon channel region is not completely depleted because the negative bias voltage from the top gate to the channel region is not uniform and is dependent on the channel length. Thus, the OFF-current exists and is within the range from 0.001 nA to 0.1 nA.

Generally, the OFF-current when the third patterned electrode (top gate) is partially overlapped with at least one of the pair of second electrodes (source/drain) is larger than the OFF-current when the third patterned electrode (top gate) is not overlapped with neither of the second electrodes (source/drain).

According to the above discussion, it is apparent that the present invention discloses a double gate thin-film transistor and a method for forming the thin-film transistor, using a poly-silicon film by direct deposition at low temperatures so as to simply the processing and improve electrical characteristics. Therefore, the present invention is new, useful and non-obvious.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A double-gate thin-film transistor, comprising:
a first patterned electrode formed on a substrate;
a first dielectric layer, covering the first patterned electrode and the substrate;
a poly-silicon film, formed by direct deposition on the first dielectric layer so as to form between the poly-silicon film and the first dielectric layer an incubation layer comprising amorphous silicon;
a pair of second patterned electrodes, formed on the poly-silicon film so as to define in the poly-silicon film and the incubation layer between the second patterned electrodes a channel region corresponding to the first patterned electrode;
a second dielectric layer, covering the pair of second patterned electrodes and the channel region; and
a third patterned electrode corresponding to the channel region.

2. The double-gate thin-film transistor as recited in claim 1, wherein the substrate is selected from a group including a glass substrate, a flexible substrate and a conductive substrate having an insulating layer formed thereon.

3. The double-gate thin-film transistor as recited in claim 1, wherein the first patterned electrode comprises a material selected from a group including metal, metal oxide, poly-silicon, conductive polymer and combination thereof.

4. The double-gate thin-film transistor as recited in claim 1, wherein the first dielectric layer comprises a material selected from a group including oxide, nitride, insulating polymer and combination thereof.

5. The double-gate thin-film transistor as recited in claim 1, wherein the pair of second patterned electrodes comprise a material selected from a group including metal, metal oxide, poly-silicon, conductive polymer and combination thereof.

6. The double-gate thin-film transistor as recited in claim 1, wherein the second dielectric layer comprises a material selected from a group including oxide, nitride, insulating polymer and combination thereof.

7. The double-gate thin-film transistor as recited in claim 1, wherein the third patterned electrode is at least partially overlapped with the pair of second patterned electrodes.

8. The double-gate thin-film transistor as recited in claim 1, wherein the third patterned electrode is not overlapped with neither of the second patterned electrodes.

9. The double-gate thin-film transistor as recited in claim 1, wherein the third patterned electrode comprises a material selected from a group including metal, metal oxide, poly-silicon, conductive polymer and combination thereof.

10. The double-gate thin-film transistor as recited in claim 1, wherein the third patterned electrode is a transparent conductive electrode.

11. The double-gate thin-film transistor as recited in claim 10, wherein the transparent conductive electrode comprises indium-tin oxide (ITO).

12. A method for forming a double-gate thin-film transistor, comprising steps of:
forming a first patterned electrode on a substrate;
forming a first dielectric layer, covering the first patterned electrode and the substrate;
forming a poly-silicon film by direct deposition on the first dielectric layer so as to form between the poly-silicon film and the first dielectric layer an incubation layer comprising amorphous silicon;
forming a pair of second patterned electrodes on the poly-silicon film, so as to define in the poly-silicon film and the incubation layer between the second patterned electrodes a channel region corresponding to the first patterned electrode;
forming a second dielectric layer, covering the pair of second patterned electrodes and the channel region; and
forming a third patterned electrode corresponding to the channel region.

13. The method as recited in claim 12, wherein the substrate is selected from a group including a glass substrate, a flexible substrate and a conductive substrate having an insulating layer formed thereon.

14. The method as recited in claim 12, wherein the first patterned electrode comprises a material selected from a group including metal, metal oxide, poly-silicon, conductive polymer and combination thereof.

15. The method as recited in claim 12, wherein the first dielectric layer comprises a material selected from a group including oxide, nitride, insulating polymer and combination thereof.

16. The method as recited in claim 12, wherein the pair of second patterned electrodes comprise a material selected from a group including metal, metal oxide, poly-silicon, conductive polymer and combination thereof.

17. The method as recited in claim 12, wherein the second dielectric layer comprises a material selected from a group including oxide, nitride, insulating polymer and combination thereof.

18. The method as recited in claim 12, wherein the third patterned electrode is at least partially overlapped with the pair of second patterned electrodes.

19. The method as recited in claim 12, wherein the third patterned electrode is not overlapped with neither of the second patterned electrodes.

20. The method as recited in claim 12, wherein the third patterned electrode comprises a material selected from a group including metal, metal oxide, poly-silicon, conductive polymer and combination thereof.

21. The method as recited in claim 12, wherein the third patterned electrode is a transparent conductive electrode.

22. The method as recited in claim 21, wherein the transparent conductive electrode comprises indium-tin oxide (ITO).
